(19) United States
(12) Patent Application Publication
(10) Pub. No.: US 2025/0151341 A1
(43) Pub. Date: May 8, 2025

(54) TRANSISTOR, POWER ELECTRONIC SWITCHING DEVICE AND METHOD FOR MANUFACTURING A TRANSISTOR

(71) Applicant: Hitachi Energy Ltd, Zürich (CH)

(72) Inventors: Giovanni ALFIERI, Möriken (CH); Gianpaolo ROMANO, Baden (CH); Andrei MIHAILA, Rieden (CH)

(21) Appl. No.: 18/836,320

(22) PCT Filed: Jan. 25, 2023
(86) PCT No.: PCT/EP2023/051782

§ 371 Date: Aug. 6, 2024

(30) Foreign Application Priority Data
Feb. 17, 2022 (EP) 22157298.5

(51) Int. Cl. H10D 62/10; H10D 30/01; H10D 30/66; H10D 62/13; H10D 62/60; H10D 62/832; H10D 62/834; H10D 84/01

(52) U.S. Cl. CPC H10D 62/105; H10D 30/0297; H10D 30/668; H10D 62/153; H10D 62/154; H10D 62/60; H10D 62/8325; H10D 62/834; H10D 84/013

(57) ABSTRACT

A wide bandgap semiconductor power transistor comprising an epitaxial layer of a first conductivity type, at least one well region of a second conductivity type formed in a selected area of the epitaxial layer, at least one terminal region, in particular a source region, of the first conductivity type formed in or adjacent to the at least one well region, at least one terminal electrode, in particular a source electrode, formed at least partly on a surface of a first part of the at least one terminal region, and at least one resistive region formed within the at least one terminal region, the at least one resistive region comprising amphoteric impurities.

### CROSS-REFERENCE TO RELATED APPLICATIONS

The present application is a national stage entry of International Patent Application No. PCT/EP2023/051782, filed on Jan. 25, 2023, which claims priority to European Patent Application No. 22157298.5, filed on Feb. 17, 2022, which are both hereby incorporated herein by reference as if set forth in full.

### FIELD OF THE INVENTION

The present disclosure relates to a transistor, in particular a wide bandgap power transistor, comprising an epitaxial layer, at least one well region and at least one terminal region, in particular a source region. The present disclosure further relates to a power electronic switching device comprising a plurality of switching cells and a method for manufacturing a transistor, in particular a SiC power transistor.

### BACKGROUND OF THE INVENTION

Transistors are used in many applications, including power electronics. It is generally desirable for transistors, such as Metal-Oxide-Semiconductor Field Effect Transistor (MOSFETs), to be able to withstand so-called short-circuit conditions for a specified time. For example, it may be desirable to provide power transistors with a short-circuit withstand time (SCWT) of at least 10 μs. The SCWT may be used by a control circuit to identify a fault in a corresponding power circuit and to de-energize it.

At the same time, it is desirable to minimize conduction losses of transistors, and in particular of power transistors. Low conduction losses generally lead to higher saturation current densities in the semiconductor material, which in turn shortens their SCWT.

Accordingly, it is a challenge to describe improved devices and methods for their manufacturing which allow to balance the aim of low conduction losses with the aim of a predetermined SCWT.

### SUMMARY OF THE INVENTION

Embodiments of the disclosure relate to a transistor, a power electronic switching device and a method for manufacturing a transistor that allow to selectively increase the resistivity inside one of the terminal regions to control a voltage drop within the transistor structure and thus control a corresponding SCWT of the transistor. This is achieved, at least in part, by introduction of at least one resistive region comprising amphoteric impurities.

According to a first aspect, a transistor, in particular a wide bandgap semiconductor power transistor, is disclosed. The transistor comprises an epitaxial layer of a first conductivity type, at least one well region of a second conductivity type formed in a selected area of the epitaxial layer, at least one terminal region, in particular a source region, of the first conductivity type formed in or adjacent to the at least one well region, at least one terminal electrode, in particular a source electrode, formed at least partly on a surface of a first part of the at least one terminal region, and at least one resistive region formed within the at least one terminal region, the at least one resistive region comprising amphoteric impurities.

By introducing at least one resistive region formed within at least one terminal region, a resistance of the terminal region can be increased and other parts of the transistor structure can be protected by reducing a voltage drop therein. The use of amphoteric impurities allows to closely control the resistivity of the resistive region and, therefore, the overall resistance of the terminal region. Among others, the inventors have found that the resistivity of a terminal region implanted with amphoteric species can be controlled, for example, based on the implantation dose or an activation temperature of the resistive region.

In addition, the inventors have found that the use of amphoteric dopants results in no or only an insignificant amount of crystal defects in the epitaxial layer in general and the at least one resistive region formed within at least one terminal region in particular. For example, in case of implanting manganese (Mn) into silicon carbide (SiC) used as wide bandgap semiconductor material, a concentration of Z1/2 lattice defects may lie at or below 1e11 cm⁻³. For other amphoteric species and/or implantation doses, the concentration of Z1/2 lattice defects is still at a relatively low level, such as at or below 1e13 cm⁻³. This can be attributed to the formation of C interstitials, i.e. C atoms knocked out of their site in the crystal lattice during implantation. Such interstitials can diffuse even at room temperature and can annihilate Z1/2, corresponding to a vacant C site in the crystal lattice. In contrast, implantation of other types of dopants may lead to an increased concentration of lattice defects. For example, implantation of protons, helium (He) or argon (Ar) may lead to a relatively high concentration of Z1/2 lattice defects at or above 1e15 cm⁻³, e.g. one or more orders of magnitude above the concentration of Z1/2 lattice defects achieved using amphoteric dopants.

The at least one resistive region may comprise at least one of manganese (Mn), and vanadium (V) as amphoteric dopants. These dopants may operate, selectively, as charge acceptors or donors in common wide bandgap semiconductor materials useful for power electronics, in particular in silicon carbide (SiC), such as 4H—SiC or 6H—SiC.

Using common semiconductor processing steps and parameters, the resistivity of the terminal region can be modulated to lie in excess of 10 Ωcm, for example somewhere in the range between 20 Ωcm and 20 kΩcm, which is a useful range for controlling the SCWT of a power transistor.

Different structures within the terminal region may be obtained by using various implantation techniques. For example, it is possible to fully separate second sub-regions of the terminal region comprising essentially no amphoteric impurities by one or more first sub-region in which an amphoteric impurity is present. By patterning the at least one terminal region, the current density in different parts of the terminal region can be closely controlled.

The described terminal structure is applicable to many different transistor types, including metal-oxide-semiconductor field-effect transistors (MOSFETs), metal-insulator-semiconductor field-effect transistors (MISFETs), junction field-effect transistors (JFETs) and insulated gate bipolar transistors (IGBTs). Moreover, the described terminal structure can be used in different configurations, including planar and trench configurations.

According to a second aspect, a power electronic switching device is disclosed. The device comprises a plurality of switching cells electrically connected in parallel, wherein each switching cell of the plurality of switching cells comprises a transistor according to the first aspect. By using several of the above transistors in parallel, a relatively high current rating can be obtained, as often required in power electronics.

Features and advantages described in connection with an individual transistor may also be used in more complex devices, such as power electronic switching devices comprising a plurality of transistor cells arranged on a common substrate and/or electrically connected in parallel.

The transistor or power electronic switching devices according to the above aspects may have a voltage rating of 600 Volts or above.

According to a third aspect, a method for manufacturing a transistor, in particular a wide bandgap semiconductor power transistor, is provided. The method comprises the steps of:
epitaxially growing a semiconductor layer of a first conductivity type;
forming at least one well region of a second conductivity type formed in a selected area of the epitaxial layer;
forming at least one terminal region, in particular a source region, of the first conductivity type in or adjacent to the at least one well region; and
implanting an amphoteric dopant in at least a part of the at least one terminal region.

The above steps allow to manufacture a transistor according to the first aspect using well-established processing steps used in the manufacturing of power electrical devices.

For example, an implantation depth of the amphoteric dopant and thus the shape of the resistive region may be controlled using appropriate implantation energies in the range of 50 to 1000 keV.

Moreover, the overall resistivity of the resistive region can be controlled by implanting the amphoteric dopant using an implantation dose in the range of 10¹⁰ cm⁻² to 10¹⁴ cm⁻².

In at least one embodiment, the method further comprises annealing at least one resistive region comprising the implanted amphoteric dopants at a first temperature T₁, wherein the first temperature T₁ is selected based on a target resistivity p of the terminal region. According to experiments by the inventors, there is a relationship between an activation temperature and the resistivity of the doped and activated resistive regions, which can be exploited to limit a peak current through the transistor during short-circuit conditions. In particular, if a source region is doped with the amphoteric dopant, a current density in a neighbouring channel region can be reduced, which is defined by the gate-to-source potential (V_{GS}) in power transistors.

The present disclosure comprises several aspects of a semiconductor device, in particular a terminal structure of a transistor, and a method for manufacturing such a transistor and terminal. Every feature described with respect to one of the aspects is also disclosed herein with respect to the other aspects, even if the respective feature is not explicitly mentioned in the context of the specific aspect.

### BRIEF DESCRIPTION OF THE DRAWINGS

The accompanying figures are included to provide a further understanding. In the figures, elements of the same structure and/or functionality may be referenced by the same reference signs. It is to be understood that the embodiments shown in the figures are illustrative representations and are not necessarily drawn to scale.

FIG. 1 shows a schematic cross-section through a terminal region of a transistor.

FIGS. 2a and 2B shows schematic cross-sections through vertical power transistors in a planar and trench configuration, respectively.

FIGS. 3 to 9 show various steps of a process for manufacturing a vertical power MOSFET.

FIG. 10 shows a relationship between the resistivity of a semiconductor region with amphoteric impurities in dependence on an annealing temperature.

FIGS. 11 to 13 show different characteristics of a transistor device comprising a resistive region with amphoteric impurities.

FIG. 14 shows cross-sections through five potential configurations of a terminal region.

FIG. 15 shows perspective views of seven further potential configurations of a terminal region.

FIG. 16 shows steps of a method for manufacturing a transistor.

### DETAILED DESCRIPTION OF THE INVENTION

While the disclosed invention is applicable to many different types of semiconductor transistors, a particular focus is placed on power MISFETs, in particular power MISFETs implemented using wide bandgap semiconductor materials, such as SiC. An important feature of a MISFET is the ability to withstand short circuit conditions for a given time, e.g. more than 10 μs. During this time, the so-called short-circuit withstand time (SCWT), associated control circuit can identify and de-energize the fault. In power electronics, SiC MISFETs are typically designed with relatively short channel length and small pitches between neighboring switching cells. Such a compact design is beneficial to minimize conduction losses of individual transistors as well as complex power electronic switching devices. On the other hand, this leads to relatively high saturation current densities which, in turn, shorten the SCWT.

To achieve a desired design trade-off between low conduction losses and a desired SCWT, according to at least one implementation example, a terminal region of a SiC MISFET, for example an n++ source region, is implanted with a high resistive region, in order to obtain a trade-off between conduction losses and SCWT. The resistivity p of the high resistive region can be modulated by various processing parameters as described below.

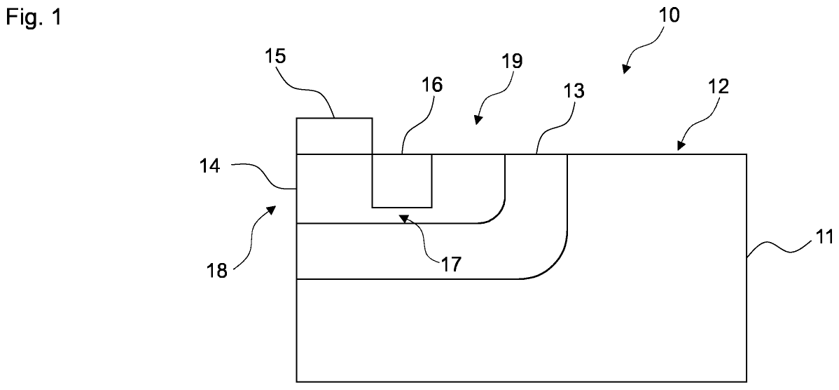

FIG. 1 shows an example of such a terminal structure. In particular, it shows a cross-section through part of a transistor 10 comprising an epitaxial layer 11, also referred to as epi-layer 11 or drift layer in the following. The epi-layer 11 may be formed by n-type SiC. In a part of the epi-layer 11 close to its front side or upper surface 12, a well region 13 may be formed by doping the epi-layer 11 with a suitable dopant. For example, a p-well may be formed by selectively doping the epi-layer 11 with an electron accepting element. In the example presented in FIG. 1, a channel region of the transistor 10 is located within this well region 13. In a following processing step, a terminal region 14, such as a source region, may be formed in part of the well region 13. The terminal region 14 typically has the same conductivity type as the epi-layer 11, but may have a higher doping concentration. For example, an n++ source region may be formed by implanting dopants acting as electron donors. At least a part of the upper surface 12 of the terminal region 14 is in touch with a terminal electrode 15. For example, a metallization layer may be used to connect an outside terminal to the terminal region 14.

In the described example, the terminal region 14 further comprises a resistive region 16. In the sense of this disclosure, a resistive region has a resistivity that is considerably higher than the remaining parts of the terminal region 14. This is achieved, at least in part, by introduction of amphoteric impurities within the resistive region 16. Since amphoteric impurities can act both as donors and acceptors for charge carriers, it greatly reduces the conductivity of all kinds of doped semiconductor materials, including highly doped p++ or n++ regions of a SiC epi-layer.

The resistive region 16 can take many different configurations. As shown in FIG. 1, it may extend from the upper surface 12 partly through the terminal region 14, thereby forming a relatively narrow connecting part 17 connecting a left and right sub-region 18 and 19 of the terminal region 14, respectively. Within the resistive region 16, the depletion of charge carriers by the amphoteric dopant reduces a current. Within the connecting part 17, due to its limited spatial extent, the overall current is also limited. Thus, a short-circuit current flowing through the epi-layer 11, the well region 13, the terminal region 14 and the terminal electrode 15 can be greatly reduced, with most of a corresponding voltage drop occurring within the terminal region 14.

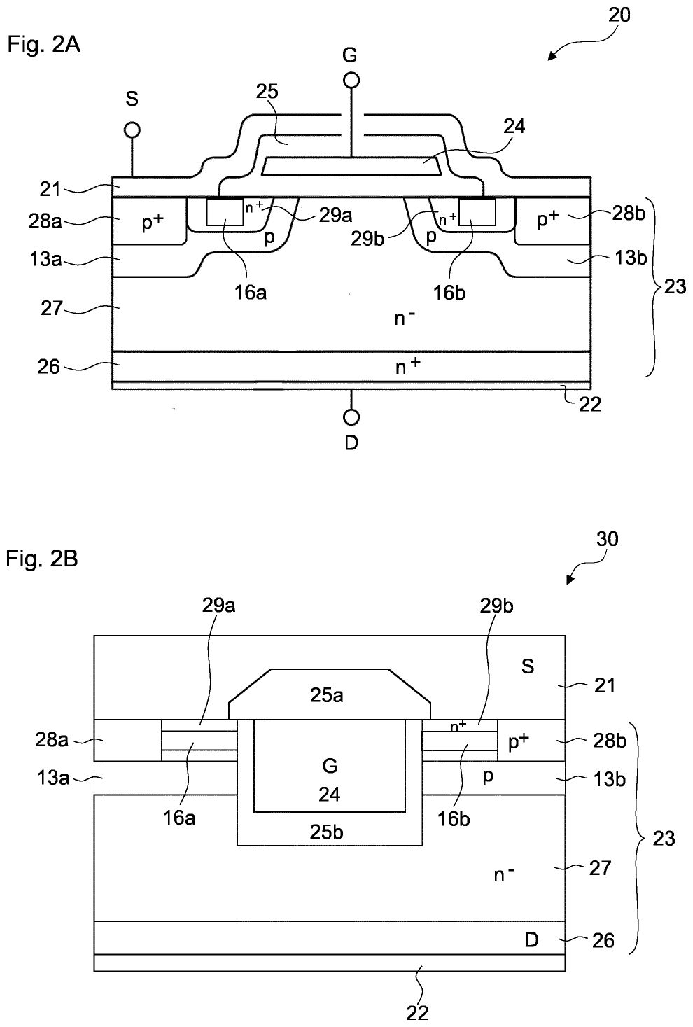

FIGS. 2A and 2B show how such a terminal electrode can be used in a vertical power transistor.

In particular, FIG. 2A shows a modified planar VDMOS 20. The VDMOS 20 comprises a source electrode 21 and a drain electrode 22 arranged on opposite surfaces of a semiconductor transistor structure 23. Between the source electrode 21 and the top surface of the semiconductor transistor structure 23, an insulated gate structure is formed, comprising a gate electrode 24 and surrounding insulation layers 25. The semiconductor transistor structure 23 comprises, from bottom to top, and a n⁺-type substrate layer 26 acting as drain region, an n⁻-type drift layer 27 corresponding to the epi-layer 11 of FIG. 1, an optional n⁺ buffer layer (not shown) between the substrate layer 26 and the epi-layer 11, two p-type well regions 13a and 13b, two n⁺-type source regions 29a and 29b corresponding to the terminal region 14 of FIG. 1, and, in addition, two p⁺-type well contact regions 28a and 28b electrically connecting the source electrode 21 with the well regions 13a and 13b.

In the example presented in FIG. 2A, each one of the source regions 29a and 29b comprises a resistive region 16a and 16b as explained above with regard to FIG. 1. That is to say, in the modified VDMOS 20 according to FIG. 2, the resistivity of both parts of the source regions 29a and 29b is increased and controlled as described above and below.

FIG. 2B shows a trench gate power transistor 30 comprising a gate electrode 24 in a trench arranged between two n⁺-type source regions 29a and 29b and p-type well regions 13a and 13b. The gate electrode is insulated by an upper insulation layer 25a from the source electrode 21 and by a lower insulation layer 25b from the semiconductor transistor structure 23. Most other components of the trench gate power transistor 30 correspond to the corresponding parts of the planar VDMOS 20 described above with respect to FIG. 2A and are therefore not described here again.

In the example presented in FIG. 2B, each one of the source regions 29a and 29b comprises a resistive region 16a and 16b, respectively, configured as a vertical sub-layer of the respective terminal regions 29a and 29b.

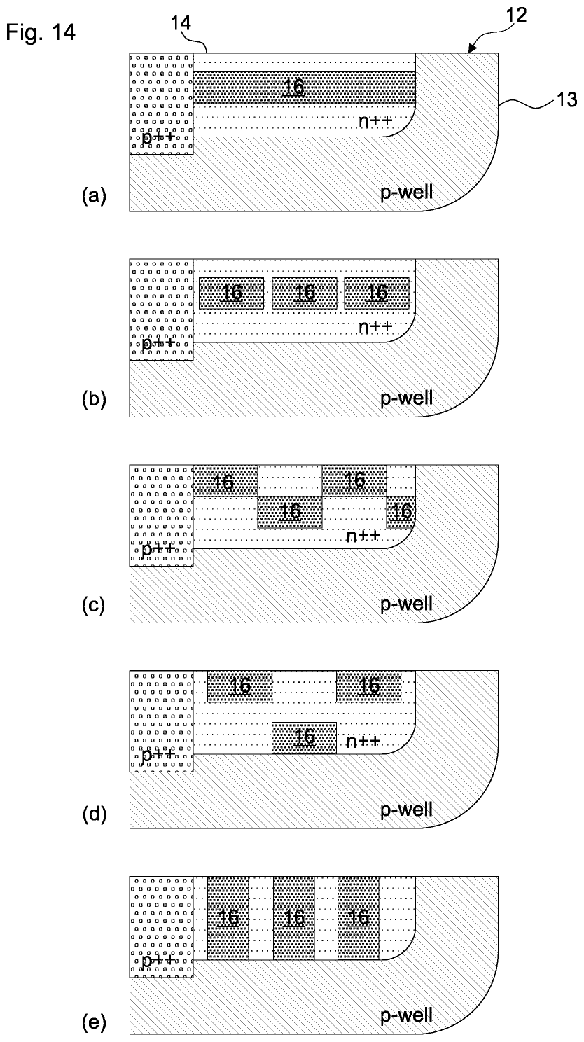

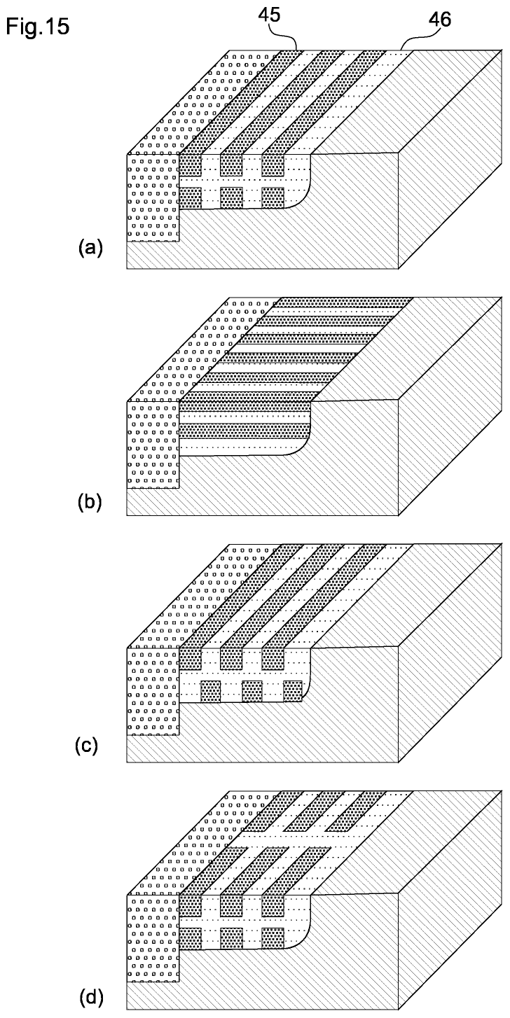

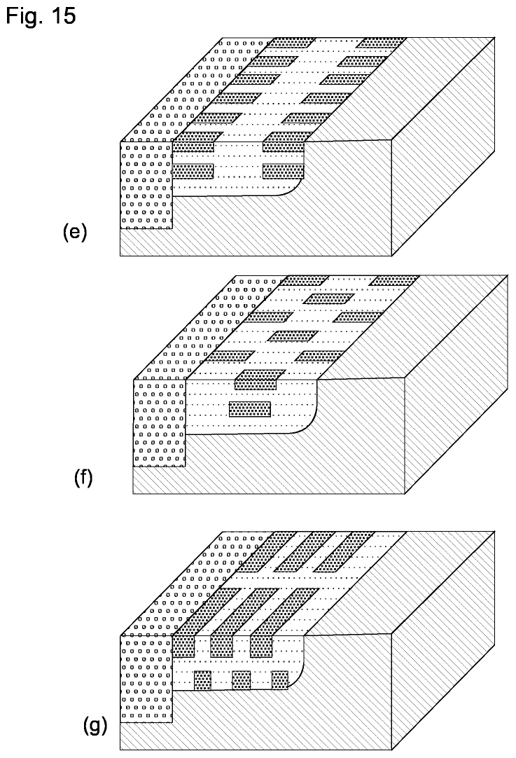

It is noted that the specific configurations of the resistive regions 16a and 16b shown in FIGS. 2A and 2B are presented as an example, and that other configurations, such as the configurations shown in FIGS. 14(a) to 15(g) may be used in each of the disclosed transistor devices.

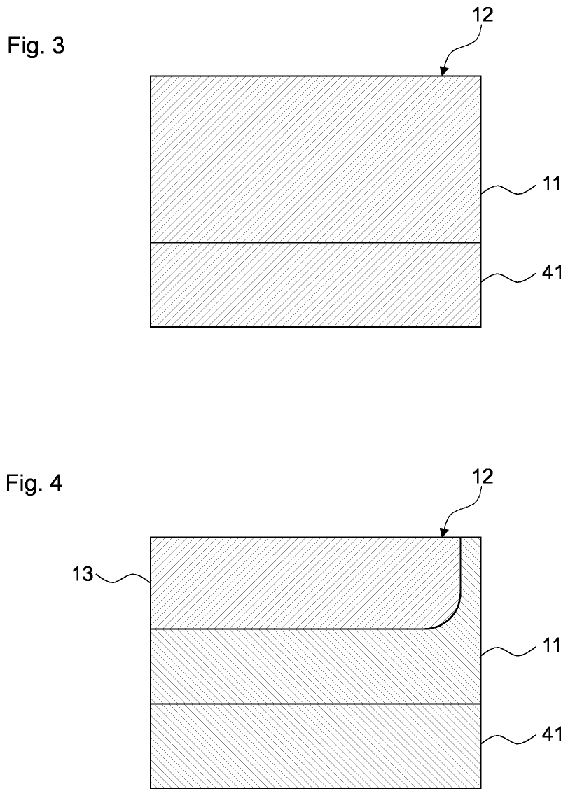

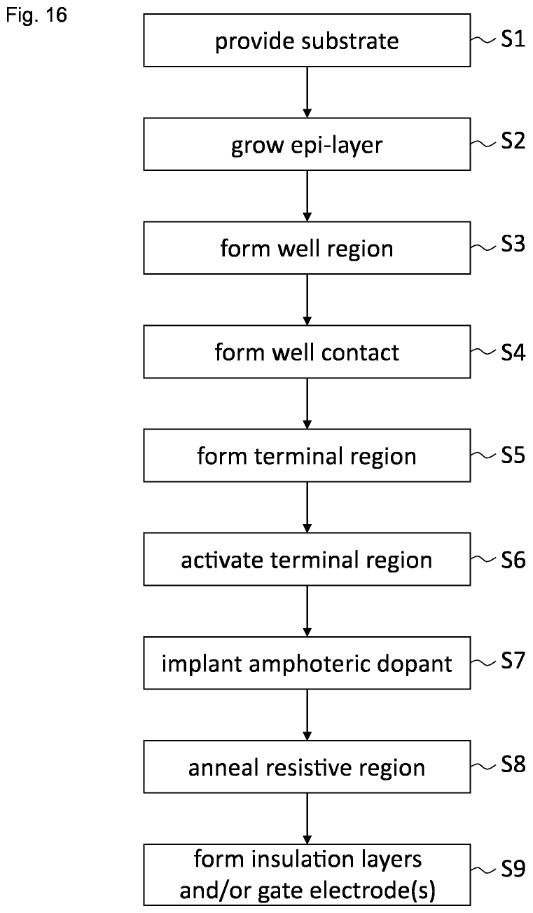

Next, with reference to FIGS. 3 to 9 as well as the flowchart according to FIG. 16, various stages in the manufacturing of a power transistor 40, such as a vertical power MOSFET, will be explained.

Referring first to FIG. 3, in a first step S1, a substrate 41 is provided. For example, an n-type SiC substrate may be provided. The substrate 41 may correspond to a backside layer or drain region of the in the finished power transistor 40. For example, Nitrogen (N) or Phosphorus (P) may be used as dopant for making n-type regions. A maximum doping concentrations of the drain region may lie in a range between 1·10¹⁷ cm⁻³ and 5·10²⁰ cm⁻³.

In a subsequent step S2, an epi-layer 11 is grown on the substrate 41, as still shown in FIG. 3. In the described example, an n-type SiC epi-layer may be grown on the substrate 41. The epi-layer 11 may correspond to a drift layer in the finished power transistor 40. Depending on the voltage class of the power transistor 40, a maximum doping concentration of the drift layer may be in a range between 1·10¹⁴ cm⁻³ and 1·10¹⁷ cm⁻³.

Referring next to FIG. 4, a photolithographic mask (not shown) may be formed on an upper surface 12 of the epi-layer 11 to selectively cover parts of the upper surface 12, before in a step S3 a remaining part of the surface 12 is doped using an appropriate dopant to form a well region 13. For example, Aluminum (Al), Boron (B) or Gallium (Ga) species, or any combination of the above, with or without n-type dopants, may be implanted to form a p-type well. That is to say, p-type regions may be formed by implantation of Al or B or Ga, but also by co-implanting Al/B, Al/Ga, B/Ga, or even by implanting Al/N, B/N etc. A maximum doping concentrations of the well region 13 may be 1-1016 cm⁻³ or above.

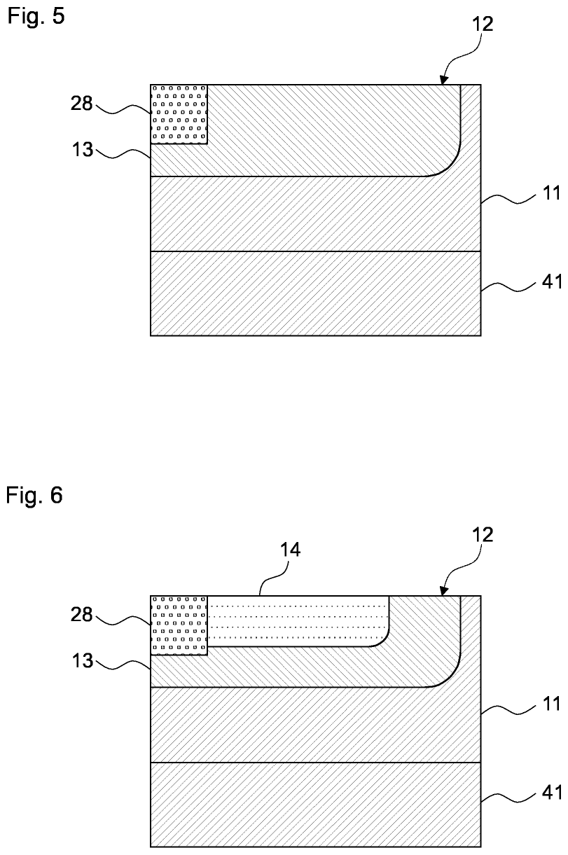

Referring next to FIG. 5, in an optional step S4, a modified or new mask may be used to form a well contact region 28. The well contact region 28 may be a p++-doped area. A maximum doping concentrations of the well contact region 28 may lie in a range between 1·10¹⁷ cm⁻³ and 5.10²⁰ cm⁻³. In the finished power transistor 40, the well contact region 28 may prevent a floating of the electrical potential of the well region 13 during operation of the transistor device.

Referring next to FIG. 6, in a step S5, a terminal region 14 may be formed using yet another photolithographic mask. For example, a highly doped n++ region may be formed within the p-well region 13 to form a source region of the power transistor 40. A maximum doping concentrations of the source region may lie in a range between 1·10¹⁷ cm⁻³ and 5.10²⁰ cm⁻³. The terminal region 14 shown in FIG. 6 may be formed by implantation of nitrogen (N) or phosphorus (P) into the SiC base material.

Then, in a further step S6, the dopant species implanted in step S5 may be activated. For example, the implanted dopants may be activated at a relatively high temperature, e.g. for 30 minutes at a temperature of 1600° C.

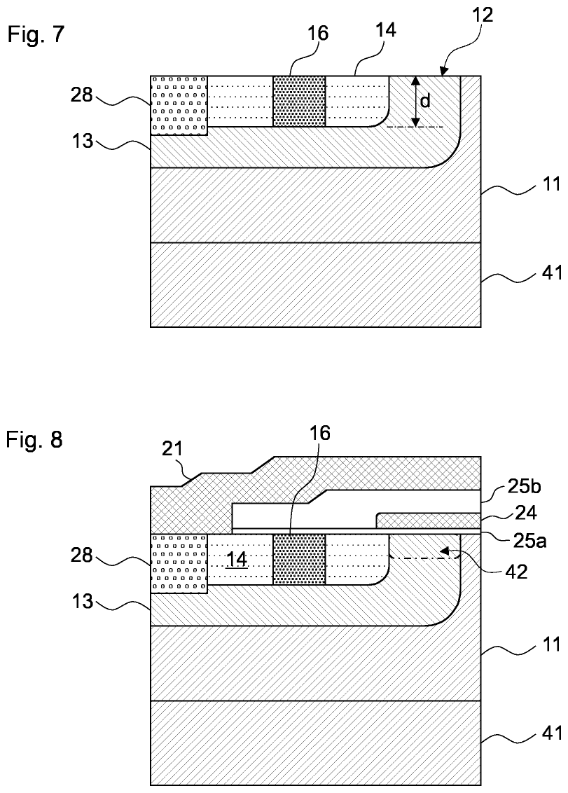

Referring next to FIG. 7, in a further step S7 an amphoteric dopant is implanted in at least part of the terminal region 14 to form a resistive region 16. This may be achieved using another photolithographic mask (not shown). The SiC material of the epi-layer 11 is doped through one or more openings in the mask using an amphoteric dopant species. In the described process, either Mn or V are used as dopants. However, in certain situations other amphoteric dopants may be used.

For example, ion implantation and/or plasma ion implantation may be used. Step S7 may be performed at room temperature with implantation energy chosen so that the depth d of the implanted amphoteric impurities matches the depths of the terminal region 14 as shown in FIG. 7. Alternatively, a lower implantation energy may be used to result in a shallower implantation of amphoteric impurities.

The introduction of amphoteric impurities greatly increases the resistivity of the terminal region 14 within the resistive region 16. For example, an initial resistivity p of approximately 0.02 Ωcm of an n⁺+ source region may be increased by doping it with Mn or V to obtain an initial resistivity of about 20 kΩcm. The presence of the deep Mn or V acceptor and donor levels in the respective upper and lower part of the SiC bandgap compensates the N donor or Al acceptor doping of the surrounding wide bandgap semiconductor material. The table below shows the location of the acceptor and donor levels of Mn and V with respect to the conduction band energy E_{C} and the valence band energy E_{V}.

| Dopant species | Donor level | Acceptor level |
|---|---|---|
| Mn | E_{c} − 1.38 eV | E_{c} − 0.68 eV |
| V | E_{c} − 1.47 eV | E_{c} − 0.70 eV |

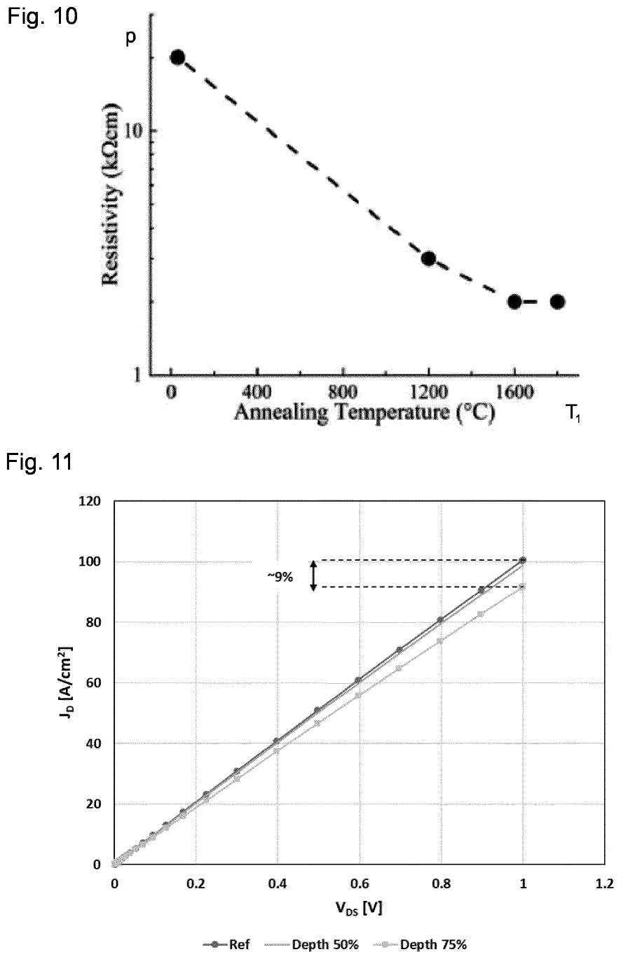

Among others, the use of amphoteric dopants allows the resistivity p of the resistive region 16 to be closely controlled in an optional annealing step S8. As shown in the logarithmic chart of FIG. 10, the resistivity p of the resistive region 16 can be controlled by selection of a corresponding annealing temperature T₁.

Without annealing, the resistivity p initially lies at about 20 kΩcm. With increasing annealing temperature T₁, applied for a given period of time, for example for 30 minutes, the resistivity p can be reduced to about 2 kΩcm in the sample structure tested. Attention is drawn to the fact that the resistance of the terminal region 14 also depends on the implantation dose used during implantation of the amphoteric impurities. Thus, the resistance of the terminal region 14 may be controlled by at least two parameters during the manufacturing of the power transistor 40.

Referring next to FIG. 8, in a further step S9, one or more insulation layers and/or electrodes may be formed on the upper surface 12 of the epi-layer 11.

In the configuration shown in FIG. 8, at first an insulation layer 25a was formed over parts of the terminal region 14, the part of the well region 13 near the upper surface 12 later forming a channel region 42 of the transistor structure (dashed in FIG. 8), as well as a neighbouring area of the epi-layer 11. On top of the first insulation layer 25a, a gate electrode 24 is formed. The gate electrode 24 is then covered by a second insulation layer 25b, which insulates a top surface of the gate electrode 24.

Thereafter, a source electrode 21 is formed on the remaining part of the upper surface 12 of the epi-layer 11 in the area of the well contact region 28 and parts of the terminal region 14. As shown in FIG. 8, the source electrode 21 also covers an upper surface of the second insulation layer 25b, as is commonly the case in vertical power transistors 40.

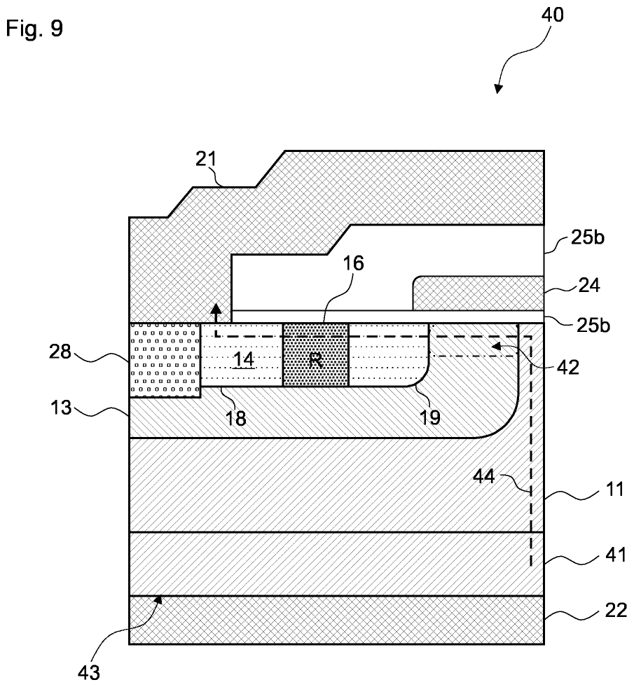

FIG. 9 shows a cross-section through part of the finished vertical power transistor 40 after formation of a drain electrode 22 on an opposite back side 43 of the substrate 41.

FIG. 9 also shows a current path 44 from the drain electrode 22, through the substrate 41, a drift layer formed by the epi-layer 11, the p-well region 13, including the channel region 42 (dashed), the terminal region 14, comprising two different n⁺+ sub-regions 18, 19 without amphoteric dopants and another sub-region in the form of the resistive region 16, to the source electrode 21. By modulating the resistivity p of the resistive region 16 and hence of the terminal region 14, a short circuit current can be controlled without overly increasing the total source-to-drain resistance RDSon during normal operation.

Technology computer-aided design (TCAD) simulations have been used to prove the proposed solution; the results are shown in FIGS. 11 to 13.

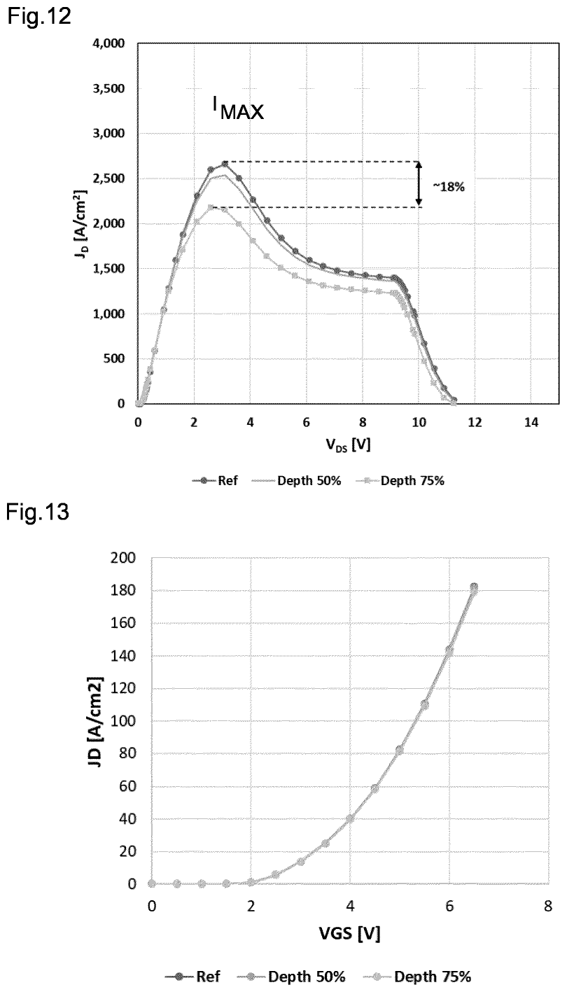

In particular, FIG. 11 shows, in a linear chart, the J_{D}/V_{DS} characteristics of the power transistor 40, and FIG. 12 shows, in a linear chart, the simulated electro-thermal short-circuit current density waveform J_{D} over time t. It can be seen that, compared to a reference design without the additional amphoteric implantation, the RDSon increases by about 9% (FIG. 11), while the peak of the SC current is reduced by approximately 18% (FIG. 12). Therefore the trade-off between conduction losses and SCWT is improved.

In general, during a short-circuit condition, a semiconductor device experiences an energy which is directly related to the maximum value of the current I_{MAX}. As shown in FIGS. 11 and 12, the disclosed design improves the SCWT with a minimal impact of the source-to-drain resistivity RDSon. The reduction of maximum or peak current I_{MAX} is due to the presence of the implanted amphoteric impurities in the resistive region 16. Since the implantation is performed in the source region, it does not affect the channel region 42.

FIG. 13 shows, in a linear chart, the transfer characteristics of the power transistor 40. Attention is drawn to the fact that characteristics of the power transistor 40 with different depths d of a resistive region coincide for the characteristic J_{D}/V_{GS} curve of the reference design without amphoteric dopants, confirming that the threshold voltage value is not affected.

FIGS. 14 and 15 show various configurations of a terminal region 14 with one or more resistive regions 16 formed therein. Attention is drawn to the fact that amphoteric impurities do not diffuse in the used wide bandgap semiconductor material and thereby stay localized in the resistive regions 16 after doping. Thus, by using conventional doping techniques, different patterns can be achieved as shown.

For example, as an alternative to the vertical segmentation shown in FIG. 7, a horizontal segmentation shown in FIG. 14 (a) may be used. For example, a single resistive region 16 may be formed as shown in FIG. 14 (a), or multiple resistive regions 16 separated by intermediate parts of the terminal region 14 not implanted with amphoteric impurities as shown in FIG. 14 (b) may be used. Moreover, due to the selection of implantation energies, individual parts of the resistive region 16 can be located at an upper surface 12 or embedded deeper in the terminal region as shown, for example, to generate a chessboard pattern as shown in FIG. 14 (c) or separated islands of amphoteric dopants as shown in FIG. 14 (d). Of course, a horizontal separation as already explained above with regard to FIG. 7 can also comprise multiple resistive regions 16 as shown in FIG. 14 (e).

FIGS. 15 (a) to 15 (g) show the formation of various first (darker) sub-regions 45 of the terminal region 14 doped with amphoteric impurities and second (lighter) sub-regions 46 of the terminal region 14 essentially free of amphoteric impurities. Such designs may be obtained, for example, by suitable masks or interference patterns used during implantation of the amphoteric species or a combination thereof.

The dimensions and implementation depths d and resistivity of the resistive regions 16 can be adjusted to extend along the entire depths of the terminal region 14 by varying the implantation energy within the range of, for example, 50 to 500 keV and/or by adjusting the doses, for example in the range of 10¹¹ to 10¹⁴ cm⁻².

The disclosed transistor structures and manufacturing techniques result in a number of benefits. This includes the modulation of the resistivity p of a terminal region 14, such as a source region, in order to adjust and control the trade-off between conduction losses and SCWT. Moreover, amphoteric impurities can be implanted irrespective of used base material, such as those used for forming and doping an n⁺+ or p⁺+ source or drain region. This enables, among others, that the implantation energy of the chosen amphoteric species can remain the same, irrespective of the dopant used for doping a corresponding terminal region, such as N, P, Al or B.

The embodiments shown in FIGS. 1 to 16 as stated represent exemplary embodiments of an improved transistor structure and method for its manufacturing. Therefore, they do not constitute a complete list of all embodiments according to the improved devices and/or methods. Actual devices, systems and methods may vary from the embodiments shown in terms of the semiconductor base materials, dopants, and processing parameters, for example.

### REFERENCE SIGNS

10 transistor
11 epitaxial layer
12 upper surface
13 well region
14 terminal region
15 terminal electrode
16 resistive region
17 connecting part
18 left sub-region
19 right sub-region
20 VDMOS
21 source electrode
22 drain electrode
23 semiconductor transistor structure
24 gate electrode
25 insulation layer
26 substrate layer
27 drift layer
28 well contact region
29 source region
30 trench gate power transistor
40 power transistor
41 substrate
42 channel area
43 back side
44 current path
45 first sub-region (amphoteric)
46 second sub-region (non-amphoteric)

1. A transistor, in particular a wide bandgap semiconductor power transistor, comprising:
an epitaxial layer of a first conductivity type;
at least one well region of a second conductivity type formed in a selected area of the epitaxial layer;
at least one terminal region, in particular a source region, of the first conductivity type formed in or adjacent to the at least one well region;
at least one terminal electrode, in particular a source electrode, formed at least partly on a surface of a first part of the at least one terminal region; and
at least one resistive region formed within the at least one terminal region, the at least one resistive region comprising amphoteric impurities.

2. The transistor of claim 1, wherein the at least one resistive region comprises at least one of Manganese, Mn, and Vanadium, V, as amphoteric dopants.

3. The transistor of claim 1, wherein a concentration of amphoteric dopants in the at least one resistive region lies in the range of 10¹⁴ to 10¹⁸ cm⁻³.

4. The transistor of claim 1, wherein
a resistivity ρ of the terminal region exceeds 10 Ωcm, and preferably lies in the range of 20 Ωcm to 20 kΩcm.

5. The transistor of claim 1, wherein a short-circuit withstand time, SCWT, of the transistor exceeds 3 μs, and preferably is or exceeds 10 μs.

6. The transistor of claim 1, wherein
an implantation depth d of the at least one resistive region lies in the range of 0 to 100%, preferably in the range of 10% to 100%, of the maximal thickness of the at least one terminal region.

7. The transistor of claim 1, wherein the at least one terminal region comprises at least three sub-regions, comprising at least one first sub-region comprising amphoteric impurities and at least one second sub-region essentially free of amphoteric impurities, in particular one of:
one first sub-region arranged horizontally between and/or separating two adjacent second sub-regions;
one first sub-region arranged vertically between and/or separating two adjacent second sub-regions;
a plurality of first sub-regions partially or completely embedded as resistive islands in a common second sub-region; and
a first plurality of first sub-regions and a second plurality of second sub-regions forming at least one of a horizontal grid, a vertical grid, a comb structure, and a chess-board pattern.

8. The transistor of claim 1, wherein the transistor is one of a metal-oxide-semiconductor field-effect transistor, MOSFET, a metal-insulator-semiconductor field-effect transistor, MISFET, a junction field-effect transistor, JFET, and an insulated-gate bipolar transistor, IGBT, in one of a planar or a trench configuration.

9. The transistor of claim 1, further comprising at least one of the following:
a substrate of the first conductivity region carrying the epitaxial layer;
at least one highly doped well contact region of the second conductivity type, electrically connecting the at least one well region with the at least one terminal electrode;
a second terminal region and a second electrode formed at least partly on a surface of the second terminal region;
at least one channel region formed within the at least one well region in proximity to a gate structure; and
a first insulation layer formed on a surface of the epitaxial layer and a gate electrode formed on a surface of the first insulation layer.

10. A power electronic switching device, comprising a plurality of transistor cells arranged on a common substrate and/or electrically connected in parallel, each transistor cell comprising a transistor according to claim 1.

11. A method for manufacturing a transistor, in particular a wide bandgap semiconductor power transistor, comprising:
epitaxially growing a semiconductor layer of a first conductivity type;
forming at least one well region of a second conductivity type formed in a selected area of the epitaxial layer;
forming at least one terminal region, in particular a source region, of the first conductivity type in or adjacent to the at least one well region; and
implanting an amphoteric dopant in at least a part of the at least one terminal region.

12. The method of claim 11, wherein the amphoteric dopant is implanted using an implantation energy in the range of 50 to 1000 keV.

13. The method of claim 11, wherein the amphoteric dopant is implanted using an implantation dose in the range of 10¹⁰ cm⁻² to 10¹⁴ cm⁻².

14. The method of claim 11, further comprising:
annealing at least one resistive region comprising the implanted amphoteric dopants at a first temperature T₁, wherein the first temperature Ti is selected based on a target resistivity ρ of the terminal region.

15. The method of claim 14, further comprising:
prior to annealing the at least one resistive region, activating the at least one terminal region at a second temperature exceeding the first temperature; and/or
after implanting the amphoteric dopant, forming at least one terminal electrode, in particular a source electrode, at least partly on a surface of at least part of the at least one terminal region.
